(19) United States
(12) Patent Application Publication
(10) Pub. No.: US 2002/0121845 A1
(43) Pub. Date: Sep. 5, 2002

(54) Piezotransformer with a large transformation ratio

(75) Inventors: Henry Gueldner, Heidenau (DE); Thomas Hanisch, Oschatz (DE); Igor Kartaschev, Dresden (DE)

Correspondence Address: OSRAM SYLVANIA INC, 100 ENDICOTT STREET, DANVERS, MA, 01923, US

(73) Assignee: PATENT-TREUHAND-GESELLSCHAFT FUER GLUEHLAMPEN MBH, MUENCHEN (DE)

(21) Appl. No.: 10/076,376

(22) Filed: Feb. 19, 2002

(30) Foreign Application Priority Data
Mar. 1, 2001 (DE) 101 09 994.0

(51) Int. Cl. H01L 41/107

(52) U.S. Cl. 310/359

(57) ABSTRACT

Piezoelectric transformer with an input and an output region. Input and/or output regions are sub-divided into sections (13-16) of inverse polarization. Depending on the number of sections, a multiplication of the transformation ratio is achieved without increasing the field strength in the piezoelectric material.

### TECHNICAL FIELD

The invention relates to piezoelectric transformers, termed piezotransformers below, for short. In particular, the invention solves problems that occur in providing piezotransformers with a high transformation ratio.

### PRIOR ART

U.S. Pat. No. 2,830,274 (Rosen) discloses the design of a piezotransformer which can supply a large transformation ratio. The piezotransformer consists of a piezoelectric material to which electrodes are applied. The electrodes can also be worked into the piezoelectric material. It is important that the electric field forming between the electrodes has a component in the direction of polarization of the piezoelectric material. The piezotransformer has a pair of input terminals and a pair of output terminals. The input terminals are connected to two or more electrodes. The piezoelectric material is set vibrating mechanically by applying an input voltage to the input terminals. The output terminals are also connected to two or more electrodes. An output voltage can be tapped at the output terminals because of the mechanical vibrations. One or more electrodes can be connected both to an input terminal and to an output terminal.

In this context, the ratio of the output voltage to the input voltage is understood by the term transformation ratio. The abovenamed document describes a piezotransformer that is subdivided into an input region and an output region. The excitation of the mechanical vibration takes place chiefly in the input region, while the generation of the output voltage takes place chiefly in the output region. The direction of polarization of the piezoelectric material differs in the two regions. However, there is only one direction of polarization within a region. The voltage between two electrodes is, of course, the integral of the electric field strength along the path between the electrodes. For the purpose of effectively transforming electric voltage into mechanical pressure, the electrodes are arranged such that the integration path between the electrodes runs as much as possible in the direction of the polarization. The transformation ratio of such a piezotransformer is therefore a function of the ratio of the integration paths between the output and input electrodes. The ratio of the essential geometric dimensions of the piezotransformer is thereby fixed for a given transformation ratio. The following relationships are important for the absolute geometric dimensions:

The efficiency of a piezotransformer is optimum only when it is operated at a frequency that effects resonant vibration. Consequently, relatively small geometric dimensions require a relatively high operating frequency. For many applications, the operating frequency should not exceed specific limits, and this stands in the way of miniaturization of the piezotransformer and thus of a reduction in costs. For example, in the case of application in operating units for gas discharge lamps, an operating frequency of 100 kHz should not be exceeded, because of the possibly long supply lead to the lamp. The piezoelectric material is suitable only up to a specific limit for the electric field strength. If high output voltages such as are achieved, for example, starting a gas discharge lamp, this gives rise to a minimum spacing for the electrodes connected to the output terminals.

### SUMMARY OF THE INVENTION

It is an object of the present invention to provide a piezotransformer in accordance with the preamble of claim 1 that permits a modification of the transformation ratio by comparison with the prior art without violating the abovenamed limitations.

This object is achieved according to the invention by virtue of the fact that the input region and/or the output region is divided into sections, mutually adjacent sections being polarized inversely to one another. Inversely means in this context that the polarization of different sections runs along parallel lines, but the direction of polarization is reversed. The electrodes are connected to the terminals such that the sections in the input region can be considered as connected in parallel, and those in the output region as connected in series. The transformation ratio can thereby be multiplied without increasing the loading of the piezoelectric material with reference to the electric field strength. The idea of the invention need not necessarily be executed simultaneously in the input region and output region. It is also possible for only the input region or only the output region to be configured according to the invention. The effect on the transformation ratio is reduced in this case.

The output region adjoins the input region. This fixes a direction. The direction in which the output region is situated when seen from the input region is denoted below as longitudinal.

According to the invention, a dimension in the longitudinal direction that corresponds to a half wavelength is selected for the input region. Data on the wavelength relate here and below to the mechanical vibration set up during operation. In the simplest case, the input region is subdivided only in two sections that preferably have the same dimensions in the longitudinal direction. The polarization in the two sections is directed either toward the connecting site of the two sections, or -away from it. A first input terminal is connected to an electrode that acts in the region of the connecting site of the two sections. Two further electrodes are fitted such that they each act in the longitudinal direction at the end of one of the two sections that is averted from the connecting site of the two sections. These two further electrodes are connected to one another and to a second input terminal.

As mentioned above, according to the invention a half wave of the mechanical vibration is formed over the input region in the longitudinal direction. As determined by the above-described arrangement according to the invention, only an electric voltage such as is required for the mechanical pressure in a section needs to be applied to the input terminals. Because of its inverse polarization according to the invention, the second section can be driven by the same input voltage, and this corresponds to connecting the two sections in parallel. By comparison with an input region corresponding to the prior art and consisting of only one section, the transformation ratio is doubled by this simple case of realization of the idea of the invention. More complicated refinements are to be found in the figures. According to the invention, a dimension corresponding to N/2 wavelengths is selected for the output region in the longitudinal direction, N being a natural number greater than 1. In the simplest case, the output region is subdivided into only 2 sections that preferably have the same dimensions in the longitudinal direction. The polarization in the two sections is directed either toward the connecting site of the two sections or away from it. Two output terminals are connected to electrodes that act at the ends of the output region with reference to the longitudinal direction. According to the invention, a whole wave of the mechanical vibration is formed for N=2 over the output region in the longitudinal direction. Because the two half waves of this whole wave are formed in sections that have inverse polarization according to the invention, the electric voltage that results over the respective section is added with reference to the output terminals, something which corresponds to connecting the two sections of the output region in series. By comparison with an output region corresponding to the prior art and consisting of only one section, this results in double the output voltage and thus double the transformation ratio, without the electric field strength in the output region being doubled.

In the simple case described above, the output region is subdivided into only two sections connected in series according to the invention. However, it is possible to undertake subdivision into as many sections as desired. According to the invention, a half wave of the mechanical vibration is formed in each section, mutually adjacent sections being polarized inversely to one another. Electrodes that are connected to the output terminals act at the ends of the output region situated in the longitudinal direction. The number of the sections into which the output region is subdivided determines the factor of voltage multiplication at the output terminals with reference to an output region with only one section.

Since a half wave of the mechanical vibration is formed in a section of the output region in the longitudinal direction, whereas a half wave of the mechanical vibration is formed in the entire input region in the longitudinal direction, the result is an integral ratio for the dimensions of the sections of the output region referred to the dimensions of the sections of the input region in the longitudinal direction, in each case.

In the previous description, it has been assumed that a higher voltage is desired for the output voltage of the piezotransformer than that fed in at the input terminals. However, it is also possible to conceive applications for a piezotransformer in the case of which a lower output voltage than the input voltage is desired. In these cases, the input terminals are to be interchanged with the output terminals. The piezotransformer is then operated in the reverse direction.

The cuboid is an obvious choice for the geometric topology of a piezotransformer according to the invention. However, the idea of the invention can also be realized in other geometric topologies. It is possible to realize the described inventive design of the piezotransformer in the shape of a disk or a ring, the longitudinal direction running radially. It is also possible to realize the described inventive design of the piezotransformer in the shape of a cylinder or a tube, the longitudinal direction running in the direction of the central axis.

As explained above, the idea of the invention can be applied both to the input region and to the output region. If the idea of the invention is supplied only to one region, it is then possible to apply to the other region other methods that meet the problems addressed in the prior art.

The idea of the invention, specifically the division of a region into sections and their connection in parallel or series in order to modify the transformation ratio, can also be realized in a way that is modified by comparison with the above discussion. For example, the input region of a piezotransformer can be subdivided into two sections that preferably have the same dimensions in the longitudinal direction. The direction of polarization is not longitudinal, but perpendicular thereto, specifically in a direction in which the geometric dimension is as small as possible. For example, in the case of a plate-shaped cuboid the input region would be polarized in the direction of the thickness of the cuboid in accordance with the modified realization of the idea of the invention. This direction may be denoted below as transversal. By contrast with the previous discussion, the polarization of the two sections need not be inverse to one another, but can be inverse or identical. In accordance with the modified realization of the idea of the invention, each section of the input region has a pair of electrodes that are suitable for building up an electric field in the transverse direction. The two sections can be connected in parallel or in series in relation to the input terminals. According to the invention, the connection of electrodes to the input terminals, and the polarization of the sections are to be selected such that a given input voltage generates an electric field that points in one section in the direction of polarization, and in the other section counter to the direction of polarization. It is thereby possible to use a reduced input voltage in the input region to generate a desired mechanical vibration, thus increasing the transformation ratio.

If, as explained above, the piezotransformer is operated in the reverse direction, the above discussion thus applies to the modified realization of the idea of the invention for the output region. It is also possible to apply the modified realization of the idea of the invention to more than two sections.

### DESCRIPTION OF THE DRAWINGS

The invention is to be explained below in more detail with the aid of a plurality of figures, in which:

FIG. 1 shows a side view of a cuboid piezotransformer according to the invention,

FIG. 2 shows a further embodiment for the input region of a cuboid piezotransformer according to the invention,

FIG. 3 shows a piezotransformer according to the invention in the shape of a ring,

FIG. 4 shows a piezotransformer according to the invention in the shape of a tube, and

FIG. 5 shows a further embodiment for the input region of a cuboid piezotransformer according to the invention.

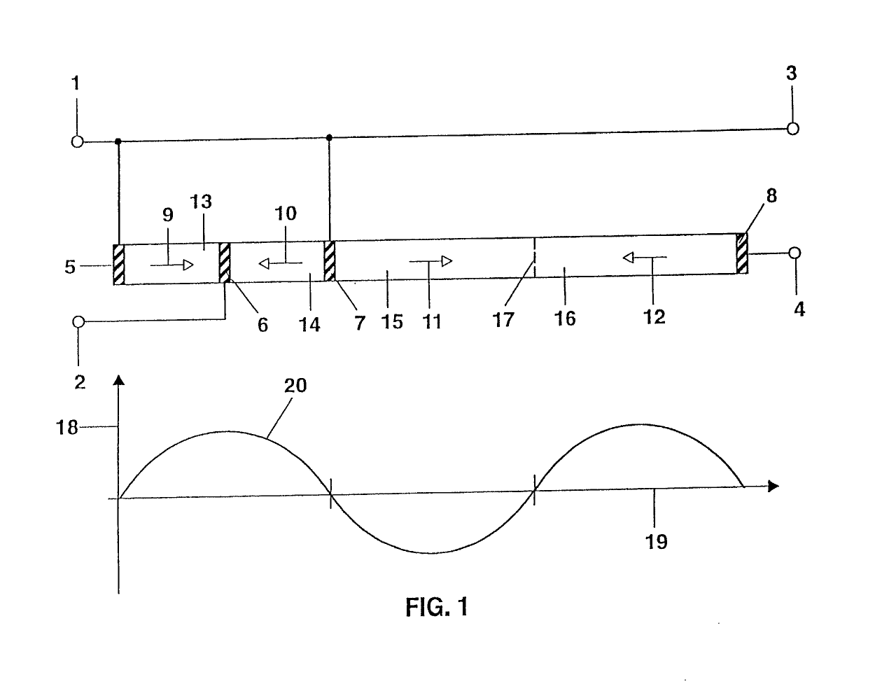

The side view of a cuboid piezotransformer according to the invention is illustrated in the upper part of FIG. 1. The piezotransformer is sectionalized into an input region and output region. The input region is subdivided into two sections 13 and 14. Their polarization runs in the longitudinal direction, the sections 13 and 14 being polarized inversely to one another. Arrows 9 and 10 indicate the polarization. Electrodes 5, 6 and 7 are applied between the sections 13 and 14 and at the ends of the input region in the longitudinal direction. The electrodes can be situated both on the surface and inside the piezotransformer. The action of internally situated electrodes is better as a rule, but the cost of production is high, in return. The electrode 6 situated between the sections 13 and 14 is connected to a first input terminal 2. The electrodes 5 and 7 situated at the ends are connected to one another and to a second input terminal 1.

The output region adjoins the section 14. It is divided into two sections 15 and 16. A dividing line 17 is drawn in to illustrate the division. The polarization of the output region runs in the longitudinal direction, the sections 15 and 16 being polarized inversely to one another. Arrows 11 and 12 indicate the polarization. An electrode 8 is applied to the end of the section 16 and thus to the end of the piezotransformer. The same general statements apply for these as were made above for the electrodes 5, 6 and 7. The electrode 8 is connected to an output terminal 4. The electrode 7 situated between the input and output regions is used for the input and output regions. In addition to the connections discussed above, it is connected to a second output terminal 3. It is also possible to duplicate the electrode 7 and assign one electrode each to the input and output. An electrical isolation between the input and output of the piezotransformer can be achieved thereby.

A diagram with the axes 18 and 19 is illustrated in the lower part of FIG. 1. The axis 19 constitutes a space axis in the longitudinal direction of the piezotransformer, while the axis 18 provides a measure of the mechanical pressure in the piezoelectric material of the piezotransformer. A curve 20 describes the variation in the mechanical pressure in the piezoelectric material of the piezotransformer over the longitudinal space axis 19. It is to be seen that a half wave is formed in the input region, while a full wave of the mechanical vibration is formed in the output region.

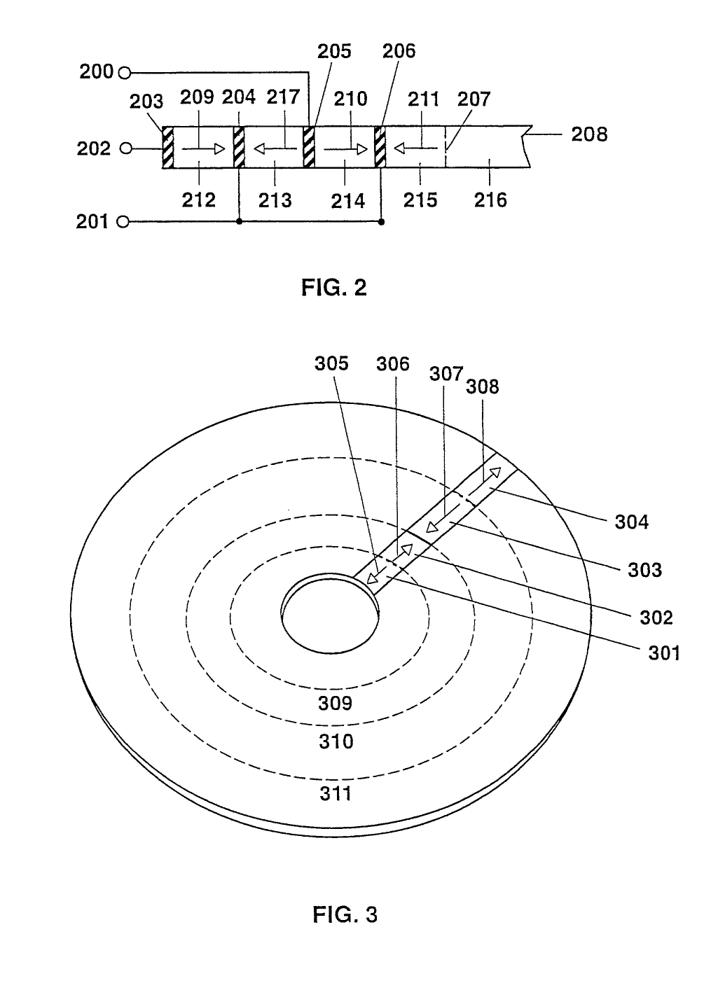

An alternative design of the input region of the piezotransformer of FIG. 1 is illustrated in FIG. 2. By contrast with FIG. 1, in FIG. 2 the input region is subdivided not in two but in four sections 212, 213, 214 and 215. Mutually adjacent sections are polarized inversely to one another according to the invention. This is illustrated by arrows 209, 217, 210 and 211. The end of the input region is indicated by a dashed line 207. Adjoining this is the first section of the output region 216. A break line 208 is intended to indicate that the output region continues, for example in the form represented in FIG. 1. The alternative input region in FIG. 2 has three essential electrodes. A first 204 is arranged between the first section 212 and the second section 213; a second 205 is arranged between the second section 213 and the third section 214; a third 206 is arranged between the third section 214 and the fourth section 215. Just like the electrodes discussed above, these electrodes can also be arranged both on the surface and inside the piezoceramic material. The first and the third electrodes 204 and 206 are connected to one another and to a first input terminal 201. The second electrode 205 is connected to a second input terminal 200. A further electrode 202, which is arranged at the edge of the input region, is not required for the principle by which the piezotransformer functions. It can be used for tapping control and regulation signals. The electric voltage required in order to excite the piezotransformer at its input terminals 200 and 201 is only a quarter as high in the case of an inventive input region in accordance with FIG. 2 as in the case of an input region that consists only of one section.

The piezotransformers in FIGS. 1 and 2 assume a cuboid topology. An annular configuration of a piezotransformer according to the invention is illustrated in FIG. 3. The inner structure is illustrated in a sectional representation. The input region is subdivided into two sections 301 and 302 that form two inner rings. The polarization of the two sections 301 and 302 is radial and inverse to one another. Arrows 305 and 306 indicate the polarization. A line 309 marks the separation of the two sections 301 and 302. A line 310 marks the separation between input and output regions. The output region consists of two sections 303 and 304 that form rings outside the input region. The polarization of the two sections 303 and 304 of the output region is radial and inverse to one another. Arrows 307 and 308 indicate the polarization. A line 311 marks the separation of the two sections 303 and 304. For reasons of clarity, no electrodes are illustrated in FIG. 3. They are situated by analogy with the positions in FIG. 1. The piezotransformer in FIG. 3 forms an annular variant of the piezotransformer of FIG. 1. It is also likewise possible for other piezotransformers according to the invention, as illustrated in FIG. 2, for example, to be of annular design. This also holds for the disk, cylinder and tube shapes. Said embodiments differ in the bandwidth of the resonance. An embodiment can be selected as a function of desired resonance characteristics.

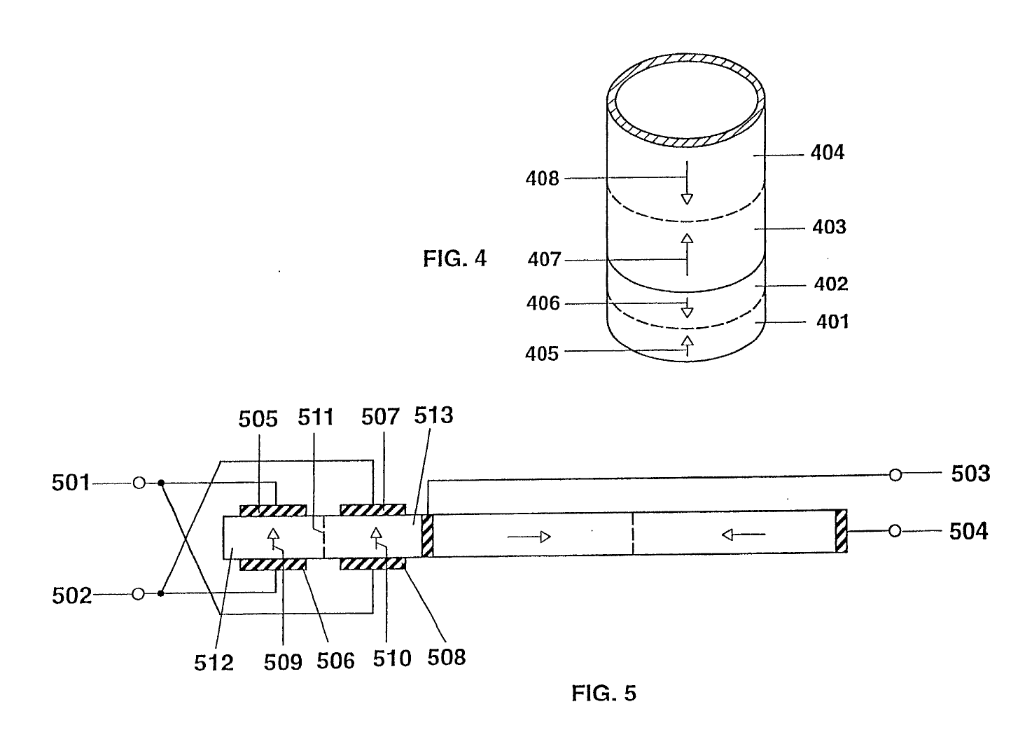

A tubular design of the piezotransformer explained in FIG. 1 is illustrated in FIG. 4. Situated one above another in the lower part of the tube are two rings 401 and 402, which form the sections of the input region. Situated above them are two rings 403 and 404, which form the sections of the output region. The polarization of the sections runs in the direction of the central axis of the tube. As is indicated by arrows 405, 406, 407 and 408, according to the invention the polarization is inverse in mutually adjacent sections.

The input region is designed in FIG. 5 in a modified form of the realization of the idea of the invention. The input region is divided according to the invention into a first and second sections 512 and 513. A line 511 indicates separation of the two sections 512 and 513. In this example, both sections 512 and 513 are transversely polarized in the same direction. Arrows 509 and 510 indicate the polarization. Each section 512 and 513 has a pair of electrodes 505, 506 and 507, 508, which are arranged such that they can generate an electric field in the direction of polarization. According to FIG. 5, the electrodes 505, 506 and 507, 508 are connected in parallel with reference to the input terminals in order to modify the realization of the idea of the invention in the exemplary embodiment. Since, as stated above, both sections of the input region 512 and 513 are polarized in the same direction, according to the invention the electrodes are therefore connected in a crosswise fashion with the input terminals. That is to say, the upper electrode 505 of the first section 512 is connected to the lower electrode 508 of the second section 513 and to a first input terminal 501; while the lower electrode 506 of the first section 512 is connected to the upper electrode 507 of the second section 513 and to a second input terminal 502. According to the invention, in the case of this connection a given input voltage generates an electric field that points in the direction of polarization in one section and points counter to the direction of polarization in the other section. According to the invention, the electric voltage that is required at the input terminals 501 and 502 in order to achieve a desired mechanical pressure is halved by this arrangement by comparison with an input region with only one section, and the transformation ratio is thereby doubled. The output region that is connected to output terminals 503 and 504 is identical to the output region in FIG. 1. The possible electrical isolation between input and output terminals is advantageous by comparison with the piezotransformer in FIG. 1.

1. A piezotransformer that is divided into an input region and an output region, characterized in that at least one of the these two regions is sub-divided into at least 2 sections (13-16, 212-215, 301-304, 401-404, 512-513), mutually adjacent sections being polarized inversely from one another in at least one region, and at least one of these two regions being polarized in the longitudinal direction.

2. The piezotransformer as claimed in claim 1, the input region being subdivided into at least two sections (13, 14, 212-215, 301, 302, 401, 402, 512, 513), characterized in that a first input terminal (2, 200) is connected to an electrode (6, 205) that is arranged such that it acts at the connecting site of two sections (13, 14, 213, 214), while a second input terminal (2, 201) is connected to electrodes (5, 7, 204, 206) that are arranged such that they act at the side of the abovementioned sections (13, 14, 213, 214) which is averted from the connecting site.

3. The piezotransformer as claimed in claim 2, characterized in that the sections (13, 14, 212-215, 301, 302, 401, 402, 512, 513) of the input region have the same dimensions in the longitudinal direction.

4. The piezotransformer with two output terminals as claimed in claim 1, the output region being subdivided into at least two sections (15, 16, 303, 304, 403, 404), characterized in that each output terminal (3, 4, 503, 504) is connected to one electrode (7, 8) each that is arranged such that it acts in the longitudinal direction only at an outer side of an externally situated section (15, 16, 303, 304, 403, 404).

5. The piezotransformer as claimed in claim 4, characterized in that the sections (15, 16, 303, 304, 403, 404) of the output region have the same dimensions in the longitudinal direction.

6. The piezotransformer as claimed in claims 3 and 5, characterized in that the ratio for the dimensions of the sections of the output region (15, 16, 303, 304, 403, 404) referred to the dimensions of the sections (13, 14, 212-215, 301, 302, 401, 402, 512, 513) of the input region is integral in each case in the longitudinal direction.

7. The piezotransformer as claimed in one of claims 1-6, characterized in that the input terminals (1, 2, 200, 201, 501, 502) are interchanged with the output terminals (3, 4, 503, 504).

8. The piezotransformer as claimed in one of claims 1-7, characterized in that the piezotransformer has the shape of a cuboid.

9. The piezotransformer as claimed in one of claims 1-7, characterized in that the piezotransformer has the shape of a disk.

10. The piezotransformer as claimed in one of claims 1-7, characterized in that the piezotransformer has the shape of a ring.

11. The piezotransformer as claimed in one of claims 1-7, characterized in that the piezotransformer has the shape of a cylinder.

12. The piezotransformer as claimed in one of claims 1-7, characterized in that the piezotransformer has the shape of a tube.

13. A piezotransformer that is divided into an input region and an output region, characterized in that at least one of these two regions is subdivided into a first and a second section (512, 513) that are transversely polarized, each section having a pair of electrodes (505, 506, 507, 508) that are connected to one another and to a pair of terminals (501, 502) such that a given voltage at said terminals (501, 502) in the first section generates an electric field that runs in the direction of polarization of the first section, while it generates in the second section an electric field that runs counter to the direction of polarization of the second section.
